(19) United States
(12) Patent Application Publication
(10) Pub. No.: US 2005/0142764 A1
(43) Pub. Date: Jun. 30, 2005

(54) Method for manufacturing semiconductor device

(75) Inventors: Sang Wook Park, Seoul (KR); Seung Cheol Lee, Kyungki-Do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyungki-Do (KR)

(21) Appl. No.: 10/878,173

(22) Filed: Jun. 28, 2004

(30) Foreign Application Priority Data
Dec. 29, 2003 (KR) 2003-98846

(51) Int. Cl. H01L 21/336

(52) U.S. Cl. 438/264; 438/297

(57) ABSTRACT

The present invention discloses a method for manufacturing a semiconductor device which forms a thick gate oxide film in a high voltage region and a thin tunnel oxide film in a cell region. The method for manufacturing the semiconductor device reduces a process time and improves uniformity of the gate oxide film in the high voltage region, by growing the gate oxide film in the high voltage region at a thickness of about 400 Å, and removing a residual nitride film in the cell region by performing an etching process using a BOE solution and an etching process using H₃PO₄ for 120 seconds and 12 minutes, respectively.

This application relies for priority upon Korean Patent Application No. 2003-98846 filed on Dec. 29, 2003, the contents of which are herein incorporated by reference in their entirety.

### BACKGROUND

1. Field of the Invention

The present invention relates to a method for manufacturing a semiconductor device, and more particularly to, a method for manufacturing a semiconductor device which can form a thick gate oxide film in a high voltage region and a thin tunnel oxide film in a cell region.

2. Discussion of Related Art

A conventional method for manufacturing a NAND type flash memory device which forms a thick gate oxide film in a high voltage region and a thin tunnel oxide film in a cell region will now be explained with reference to FIGS. 1(a) to 1(d).

Referring to FIG. 1(a), a pad oxide film 12, a nitride film 13 and an oxide film 14 are sequentially formed on a semiconductor substrate 11. Here, the pad oxide film 12 is formed at a thickness of about 50 Å, the nitride film 13 is formed at a thickness of about 200 Å, and the oxide film 14 is formed at a thickness of about 100 Å by using DCS-HTO. A photoresist film (not shown) is formed over the resulting structure to expose a high voltage region A and close a cell region B. The oxide film 14 and the nitride film 13 in the high voltage region A are removed according to a wet etching process using the photoresist film as a mask.

As shown in FIG. 1(b), a gate oxide film 15 is grown in the high voltage region A at a thickness of about 600 Å by removing the pad oxide film 12 in the high voltage region A according to a pre-cleaning process, removing the oxide film 14 in the cell region B, and performing a thermal oxidation process on the resulting structure.

As illustrated in FIG. 1(c), the residual nitride film 13 in the cell region B is removed. Therefore, the gate oxide film 15 in the high voltage region A is partially recessed, so that the gate oxide film 15 can be left at a thickness of about 360 Å. A process for removing the nitride film 13 in the cell region B will now be explained. First, an etching process using a BOE solution and an etching process using H₃PO₄ are performed for 1000 seconds and 8 minutes, respectively, by using a pattern wafer. An etching ratio by the BOE solution is calculated by measuring the thickness of the gate oxide film 15 in the high voltage region A before and after removing the nitride film 13. After the etching ratio by the BOE solution is calculated, conditions for removing the nitride film 13 for a main lot are set, and the nitride film 13 is removed. Here, the process time using the BOE solution ranges from about 900 to 1000 seconds. A wet etching time using the BOE solution is relatively long. It is thus difficult to control the thickness of the residual gate oxide film 15 in the high voltage region A due to variations of an etching ratio of the BOE wet etching equipment. In addition, a process for removing a main nitride film cannot be directly performed due to etching ratio differences by time. Accordingly, the nitride film 13 is removed as described above. On the other hand, when the nitride film 13 is removed according to sample and main processes, the whole process time increases by about 2 hours.

As depicted in FIG. 1(d), the pad oxide film 12 in the cell region B is removed according to a pre-cleaning process. Here, the gate oxide film 15 in the high voltage region A is partially recessed so that the gate oxide film 15 can be left at a thickness of about 300 Å. A tunnel oxide film 16 is grown in the cell region B at a thickness of about 75 Å according to an oxidation process. Therefore, the gate oxide film 15 in the high voltage region A maintains a thickness of about 350 Å.

In the conventional method, it takes a quite a long time to remove the residual nitride film in the cell region by using the BOE solution. Moreover, the gate oxide film wholly recessed in the high voltage region sustains a lot of loss (about 240 Å), and thus shows low uniformity.

### SUMMARY OF THE INVENTION

The present invention is directed to a method for manufacturing a semiconductor device which can solve the above problems by removing a residual nitride film in a cell region according to a main process without performing a sample process.

In order to perform the main process as the process for removing the residual nitride film in the cell region, instead of sample and main processes, an etching time using a BOE solution must be reduced. For this, a growth thickness of a gate oxide film in a high voltage region must be decreased. In the process for removing the nitride film in the cell region, an etching time using an optimized BOE solution is about 120 seconds. Here, the gate oxide film in the high voltage region must be grown at a thickness of about 400 Å. When an etching process using a BOE solution and an etching process using H₃PO₄ are performed for 120 seconds and 12 minutes, respectively, according to the optimized conditions of the process for removing the nitride film, the nitride film can be removed according to the main process, without performing the sample process. As a result, when the nitride film is removed after reducing the thickness of the gate oxide film in the high voltage region, the gate oxide film in the high voltage region is less recessed by the BOE solution, and thus uniformity of the gate oxide film is improved.

One aspect of the present invention is to provide a method for manufacturing a semiconductor device, including the steps of: sequentially forming a pad oxide film, a nitride film and an oxide film on a semiconductor substrate, and exposing the pad oxide film by removing the oxide film and the nitride film in a high voltage region; removing the pad oxide film in the high voltage region according to a pre-cleaning process, and removing the oxide film in a cell region; forming a gate oxide film in the high voltage region according to a first oxidation process; removing the residual nitride film in the cell region, by performing an etching process using a predetermined etching solution and an etching process using H₃PO₄ for 120 seconds and 12 minutes, respectively, the gate oxide film in the high voltage region being partially recessed; removing the pad oxide film in the cell region according to a pre-cleaning process, the gate oxide film in the high voltage region being partially recessed; and forming a tunnel oxide film in the cell region according to a second oxidation process.

Preferably, the gate oxide film is formed at a thickness of about 400 Å.

Preferably, the first oxidation process is performed at a temperature of 700 to 850° C. according to a wet or dry method.

Preferably, the etching solution is a BOE solution or an HF solution.

Preferably, the etching process using H₃PO₄ is performed at a temperature of 100 to 160° C.

Preferably, the gate oxide film in the high voltage region is partially grown by the second oxidation process.

### BRIEF DESCRIPTION OF THE DRAWINGS

FIGS. 1(a) to 1(d) are cross-sectional diagrams illustrating sequential steps of a conventional method for manufacturing a semiconductor device which forms a thick gate oxide film in a high voltage region and a thin tunnel oxide film in a cell region; and

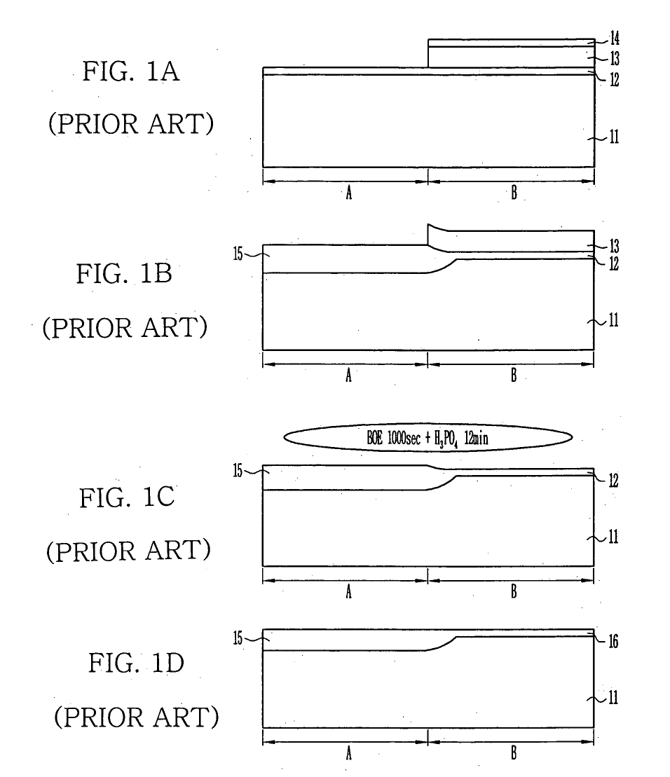

FIGS. 2(a) to 2(d) are cross-sectional diagrams illustrating sequential steps of a method for manufacturing a semiconductor device which forms a thick gate oxide film in a high voltage region and a thin tunnel oxide film in a cell region in accordance with a preferred embodiment of the present invention.

### DETAILED DESCRIPTION OF PREFERRED EMBODIMENTS

A method for manufacturing a semiconductor device in accordance with a preferred embodiment of the present invention will now be described in detail with reference to the accompanying drawings. Wherever possible, the same reference numerals will be used throughout the drawings and the description to refer to the same or like parts.

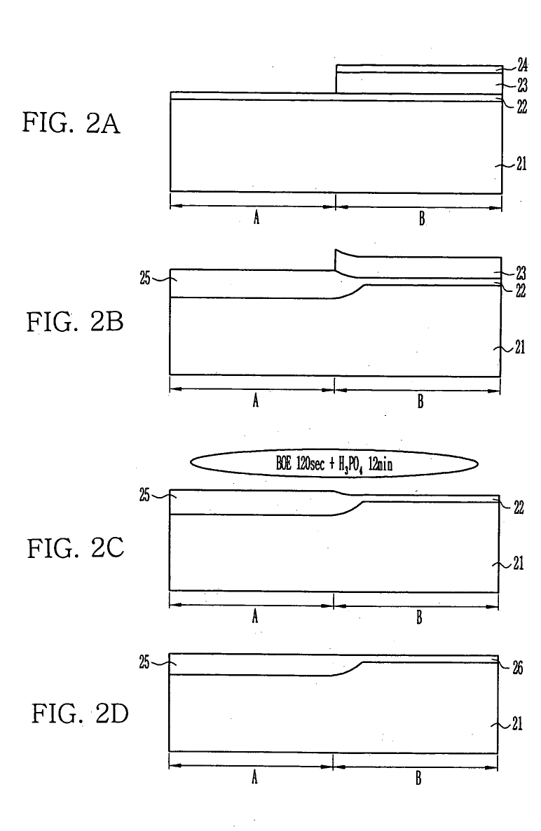

FIGS. 2(a) to 2(d) are cross-sectional diagrams illustrating sequential steps of a method for manufacturing a NAND type flash memory device which forms a thick gate oxide film in a high voltage region and a thin tunnel oxide film in a cell region in accordance with the present invention.

Referring to FIG. 2(a), a pad oxide film 22, a nitride film 23 and an oxide film 24 are sequentially formed on a semiconductor substrate 21. Here, the pad oxide film 22 is formed at a thickness of about 50 Å, the nitride film 23 is formed at a thickness of about 200 Å, and the oxide film 24 is formed at a thickness of about 100 Å by using DCS-HTO. A photoresist film (not shown) is formed over the resulting structure to expose a high voltage region A and close a cell region B. The oxide film 24 and the nitride film 23 in the high voltage region A are removed according to a wet etching process using the photoresist film as a mask, thereby exposing the pad oxide film 22.

As shown in FIG. 2(b), a gate oxide film 25 is grown in the high voltage region A at a thickness of about 400 Å by removing the pad oxide film 22 in the high voltage region A according to a pre-cleaning process, removing the oxide film 24 in the cell region B, and performing an oxidation process on the resulting structure. Here, the oxidation process is performed at a temperature of 700 to 850° C. according to a wet or dry method.

As illustrated in FIG. 2(c), the residual nitride film 23 in the cell region B is removed by performing an etching process using a BOE solution and an etching process using H₃PO₄ for 120 seconds and 12 minutes, respectively. Here, the gate oxide film 25 in the high voltage region A is recessed by about 40 Å, so that the gate oxide film 25 can be left at a thickness of about 360 Å. The BOE solution maintains a concentration of 200:1 to 300:1. An HF solution can replace the BOE solution. In addition, the etching process using H₃PO₄ is performed at a temperature of 100 to 160° C.

As depicted in FIG. 2(d), the pad oxide film 22 in the cell region B is removed according to a pre-cleaning process. Here, the gate oxide film 25 in the high voltage region A is partially recessed so that the gate oxide film 25 can be left at a thickness of about 300 Å. A tunnel oxide film 26 is grown in the cell region B at a thickness of about 75 Å according to an oxidation process. Therefore, the gate oxide film 25 in the high voltage region A maintains a thickness of about 350 Å.

As described earlier, in accordance with the present invention, the method for manufacturing the semiconductor device which forms the thick gate oxide film in the high voltage region and the thin tunnel oxide film in the cell region reduces the process time and improves uniformity of the gate oxide film in the high voltage region, by growing the gate oxide film in the high voltage region at a thickness of about 400 Å, and removing the residual nitride film in the cell region by performing the etching process using the BOE solution and the etching process using H₃PO₄ for 120 seconds and 12 minutes, respectively.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

1. A method for manufacturing a semiconductor device, comprising the steps of:
sequentially forming a pad oxide film, a nitride film and an oxide film on a semiconductor substrate, and exposing the pad oxide film by removing the oxide film and the nitride film in a high voltage region;
removing the pad oxide film in the high voltage region according to a pre-cleaning process, and removing the oxide film in a cell region;
forming a gate oxide film in the high voltage region according to a first oxidation process;
removing the residual nitride film in the cell region, by performing an etching process using a predetermined etching solution and an etching process using H₃PO₄ for 120 seconds and 12 minutes, respectively, the gate oxide film in the high voltage region being partially recessed;
removing the pad oxide film in the cell region according to a pre-cleaning process, the gate oxide film in the high voltage region being partially recessed; and
forming a tunnel oxide film in the cell region according to a second oxidation process.

2. The method of claim 1, wherein the gate oxide film is formed at a thickness of about 400 Å.

3. The method of claim 1, wherein the first oxidation process is performed at a temperature of 700 to 850° C. according to a wet or dry method.

4. The method of claim 1, wherein the etching solution is a BOE solution or an HF solution.

5. The method of claim 1, wherein the etching process using H₃PO₄ is performed at a temperature of 100 to 160° C.

6. The method of claim 1, wherein the gate oxide film in the high voltage region is partially grown by the second oxidation process.
